(19) United States
(12) Patent Application Publication
(10) Pub. No.: US 2022/0336780 A1
(43) Pub. Date: Oct. 20, 2022

(54) DISPLAY PANEL AND DISPLAY DEVICE

(71) Applicant: BOE TECHNOLOGY GROUP CO., LTD., Beijing (CN)

(72) Inventors: Yanliu SUN, Beijing (CN); Pengxia LIANG, Beijing (CN); Jiahui HAN, Beijing (CN)

(21) Appl. No.: 17/763,927

(22) PCT Filed: Jun. 9, 2020
(86) PCT No.: PCT/CN2021/099141

§ 371 Date: Mar. 25, 2022

(30) Foreign Application Priority Data
Jun. 16, 2020 (CN) 202010547392.9

(51) Int. Cl. H01L 51/52; G02B 1/02; G02B 5/20; H01L 27/32

(52) U.S. Cl. CPC H01L 51/5275; G02B 1/02; G02B 5/206; H01L 27/322; H01L 51/5253; H01L 27/3246; H01L 51/5284; H01L 2251/5369

(57) ABSTRACT

The present disclosure provides a display panel, including: a first base; a plurality of light-emitting devices on the first base; a lens layer including a plurality of lenses located on a side of the plurality of light-emitting devices away from the first base and configured to converge light beams emitted from the plurality of light-emitting devices, the plurality of lenses being one-to-one correspondence with the plurality of light-emitting devices; and a filter layer located on a side of the lens layer away from the first base and configured to enable light from the plurality of light-emitting devices to form monochromatic light after the light from the plurality of light-emitting devices passes through the filter layer.

This application claims priority from the patent application No. 202010547392.9 filed with the Chinese Patent Office on Jun. 16, 2020, the entire contents of which are incorporated herein by reference.

### TECHNICAL FIELD

The present disclosure relates to the field of display technology, and specifically relates to a display panel and a display device.

### BACKGROUND

A display panel formed by combining a quantum dot layer and an organic light-emitting diode (OLED) can realize a higher color gamut, a higher resolution and a larger viewing angle, and thus is suitable for the large-sized self-luminous display technology.

### SUMMARY

There is provided a display panel, including: a first base substrate; a plurality of light-emitting devices on the first base substrate; a lens layer including a plurality of lenses located on a side of the plurality of light-emitting devices away from the first base substrate and configured to converge light beams emitted from the plurality of light-emitting devices, the plurality of lenses being one-to-one correspondence with the plurality of light-emitting devices; and a filter layer located on a side of the lens layer away from the first base substrate and configured to enable light from the plurality of light-emitting devices to form monochromatic light after the light from the plurality of light-emitting devices passes through the filter layer.

In an embodiment, each of the plurality of lenses has at least one convex surface.

In an embodiment, surfaces of the plurality of lenses proximal to the first base substrate are convex surfaces, and surfaces of the plurality of lenses away from the first base substrate are planar surfaces.

In an embodiment, surfaces of the plurality of lenses proximal to the first base substrate are planar surfaces, and surfaces of the plurality of lenses away from the first base substrate are convex surfaces.

In an embodiment, the display panel further includes an organic encapsulation layer between the lens layer and the plurality of light-emitting devices, wherein a refractive index of the organic encapsulation layer is smaller than a refractive index of the lens layer.

In an embodiment, the display panel further includes an inorganic encapsulation layer, wherein the lens layer is an inorganic layer, and the lens layer, the organic encapsulation layer and the inorganic encapsulation layer are sequentially arranged between the filter layer and the plurality of light-emitting devices in a direction from the filter layer to the first base substrate, and the lens layer, the organic encapsulation layer and the inorganic encapsulation layer form an encapsulation structure layer for encapsulating the plurality of light-emitting devices.

In an embodiment, the lens layer includes silicon nitride, the organic encapsulation layer includes a resin, and the inorganic encapsulation layer includes silicon nitride.

In an embodiment, the refractive index of the lens layer is in a range from 1.8 to 1.9, and the refractive index of the organic encapsulation layer is in a range from 1.4 to 1.55.

In an embodiment, an angle between two light beams emitted from a center of each of the plurality of light-emitting devices respectively toward two opposite edges of a lens directly facing the light-emitting device is greater than 65°.

In an embodiment, the display panel further includes a filling layer on a side of the lens layer proximal to the filter layer, wherein a refractive index of the filling layer is smaller than a refractive index of the lens layer, and the filling layer includes a resin.

In an embodiment, the refractive index of the filling layer is in a range from 1.4 to 1.55.

In an embodiment, the plurality of light-emitting devices are configured to emit blue light. The filter layer is configured to transmit the blue light emitted from the plurality of light-emitting devices, or to generate monochromatic light with a color different from blue light under excitation of the blue light emitted from the plurality of light-emitting devices.

In an embodiment, the filter layer includes a plurality of filter portions, including a red filter portion, a green filter portion, and a blue filter portion. The red filter portion includes a red quantum dot material and scattering particles, the red quantum dot material emits red light under excitation of blue light, and the scattering particles of the red filter portion scatter light beams. The green filter portion includes a green quantum dot material and scattering particles, the green quantum dot material emits green light under excitation of blue light, and the scattering particles of the green filter portion scatter light beams. The blue filter portion is a transparent layer including scattering particles without any quantum dot layer.

In an embodiment, the display panel further includes a pixel defining layer on the first base substrate, wherein the pixel defining layer is configured to define a plurality of pixel openings in which the plurality of light-emitting devices are respectively formed.

In an embodiment, an orthographic projection of each of the plurality of lenses on the first base substrate covers and exceeds an entire orthographic projection of a pixel opening corresponding to the lens on the first base substrate.

In an embodiment, each of the plurality of light-emitting devices includes a cathode, a light-emitting layer, and an anode in a corresponding pixel opening, sequentially arranged in a direction from the filter layer to the first base substrate.

In an embodiment, the anodes of the plurality of light-emitting devices are spaced apart by the pixel defining layer, the light-emitting layers of the plurality of light-emitting devices are formed as one-piece structure, and the cathodes of the plurality of light-emitting devices form an integral structure.

In an embodiment, the display panel further includes: a second base substrate on a side of the filter layer away from the first base substrate; and an overlay layer on a side of the filter layer proximal to the first base substrate and including a resin.

In another aspect, there is provided a display device, including: the display panel as described above; and a driving circuit layer located between the first base substrate and the plurality of light-emitting devices and configured to provide driving signals for the plurality of light-emitting devices to drive the plurality of light-emitting devices to emit light.

In yet another aspect, there is provided a method for manufacturing a display panel, including: providing a first base substrate; forming a plurality of light-emitting devices on the first base substrate; forming a lens layer including a plurality of lenses on a side of the plurality of light-emitting devices away from the first base substrate, so that the plurality of lenses are in one-to-one correspondence with the plurality of light-emitting devices, wherein the lens layer is configured to converge light beams emitted from the plurality of light-emitting devices; and forming a filter layer on a side of the lens layer away from the first base substrate, wherein the filter layer is configured to enable light from the plurality of light-emitting devices to form monochromatic light after the light from the plurality of light-emitting devices passes through the filter layer.

### BRIEF DESCRIPTION OF DRAWINGS

Accompanying drawings are provided for further understanding of this disclosure and constitute a part of the specification. Hereinafter, these drawings are intended to explain the disclosure together with the following specific implementations, but should not be considered as a limitation to the present disclosure. In the drawings:

FIG. 1 is a schematic diagram showing a display panel according to a comparative example.

FIG. 2 is a schematic diagram showing a display panel according to an embodiment of the present disclosure.

FIG. 3 is a schematic diagram showing an angle at which a light beam from a center of a light-emitting device is emitted to a lens according to an embodiment of the present disclosure.

FIG. 4 is a schematic diagram showing a display panel according to an embodiment of the present disclosure.

### DETAIL DESCRIPTION OF EMBODIMENTS

Hereinafter, specific implementations of the present disclosure will be described with respect to the accompanying drawings. It will be appreciated that the specific implementations as set forth herein are merely for the purpose of illustration and explanation of the present disclosure and should not be constructed as a limitation thereof.

FIG. 1 is a schematic diagram showing a display panel according to a comparative example, and arrows in FIG. 1 indicate light beams. As shown in FIG. 1, the display panel includes a red sub-pixel region R, a green sub-pixel region G, and a blue sub-pixel region B. The display panel includes a plurality of light-emitting devices 11 emitting blue light on a base substrate 10. In addition, the display panel further includes a plurality of filter portions, including a red quantum dot layer 14r corresponding to the red sub-pixel region R, a green quantum dot layer 14g corresponding to the green sub-pixel region G, and a transmission layer 14b corresponding to the blue sub-pixel region B. A black matrix 15 is provided between different filter portions. In display, the light-emitting devices 11 emit light, so that the red quantum dot layer 14r emits red light under excitation of blue light, the green quantum dot layer 14g emits green light under excitation of blue light, and blue light direct transmits through the transmission layer 14b corresponding to the blue sub-pixel region B. Thereby, three primary colors of red, green and blue are generated. However, since other structures such as the encapsulation layer 12 and the filling layer 13 are further disposed between the light-emitting devices 11 and the filter portions and not all the light beams from a light-emitting devices 11 are collimated, the light beams emitted from the light-emitting device 11 may not only illuminate a corresponding filter portion, but also illuminate an adjacent filter portion, thereby affecting the overall brightness of the display panel, and further causing a cross color effect between different sub-pixel regions.

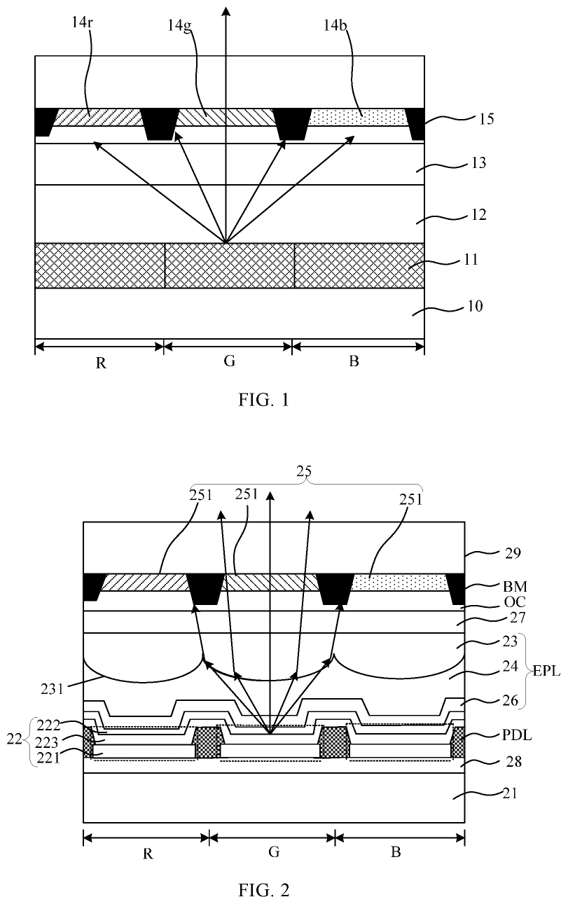

An embodiment of the present disclosure provides a display panel. FIG. 2 is a schematic diagram showing a display panel according to an embodiment of the present disclosure. As shown in FIG. 2, the display panel includes: a first base substrate 21, a light-emitting device layer, a lens layer 23, a second refractive index layer 24 (i.e., an organic encapsulation layer), and a filter layer 25.

The first base substrate 21 may be a glass base substrate, or may be a flexible base substrate made of a material including polyimide (PI) or the like.

The light-emitting device layer is disposed on the first base substrate 21, and includes a plurality of light-emitting devices 22 configured to emit blue light. For example, the light-emitting devices 22 may be OLEDs.

The lens layer 23 is disposed on a light-emitting side of the light-emitting device layer, and includes a plurality of lenses 231 disposed in one-to-one correspondence with the plurality of light-emitting devices 22 and configured to converge light beams emitted from the plurality of light-emitting devices 22. Each lens 231 is a convex lens 231 having at least one convex surface. The convex surface of the convex lens refers to a surface protruding from the lens 231.

In an embodiment, as shown in FIG. 2, a surface of each convex lens 231 facing the first base substrate 21 is a convex surface. In an embodiment, as shown in FIG. 4, a surface of each convex lens 331 facing the filter layer 35 is a convex surface. In an embodiment, both surfaces of each convex lens are convex surfaces.

It will be appreciated that converging, by the lenses 231, the light from the light-emitting devices 22 does not necessarily mean that the light beams from the light-emitting devices 22 are converged by the lenses 231 at one point, as long as a divergence angle of the light beams is decreased after the light beams pass through the lenses 231.

Optionally, a center or the middle of each light-emitting device 22 is located on an optical axis of a corresponding lens 231. The center of the light-emitting device 22 is aligned with a center of the corresponding lens 231.

The second refractive index layer 24 fits the convex surface of each lens 231. The second refractive index layer 24 shares the same surface (i.e., the convex surface) with each lens 231. A refractive index of the second refractive index layer 24 is smaller than a refractive index of the lens layer 23.

The filter layer 25 is disposed on a side of the lens layer 231 away from the light-emitting device layer, and includes a plurality of filter portions 251 disposed in one-to-one correspondence with the light-emitting devices 22. The filter portions 251 are configured to transmit the light beams from the light-emitting devices 22, or to generate light beams of a different color from the blue light under excitation of the light beams from the light-emitting devices 22.

In an embodiment of the present disclosure, the light beams emitted from a light-emitting device 22, after passing through the lens 231, are converged under a convergence action of the lenses 231, so that light beams entering a corresponding filter portion 251 are increased, and the light beams entering other light-emitting devices 22 is decreased, thereby improving the optical coupling efficiency, improving the overall display brightness of the display panel, and reducing cross color.

An embodiment of the present disclosure in which a convex surface of the lens 231 is a spherical surface is illustrated as an example. However, the convex surface of the lens 231 may have other shapes, as long as the light beams can be converged by the lens 231.

In some embodiments, as shown in FIG. 2, a surface of each lens 231 facing the first base substrate 21 is a convex surface, and a surface of the lens 231 away from the first base substrate 21 is a planar surface. The second refractive index layer 24 is located between the lens layer 23 and the first base substrate 21.

The lens layer 23 is a first inorganic layer, and the second refractive index layer 24 is an organic layer. The display panel further includes a second inorganic layer 26. The first inorganic layer, the organic layer, and the second inorganic layer 26 are sequentially stacked in a direction perpendicular to the first base substrate 21, and the first inorganic layer, the organic layer, and the second inorganic layer 26 form an encapsulation structure layer EPL encapsulating the plurality of light-emitting devices 22.

A contact surface between the second refractive index layer 24 and the lens layer 23 shares the same surface with the lens layer 23, and a contact surface between the second refractive index layer 24 and the second inorganic layer 26 shares the same surface with the second inorganic layer 26.

It will be appreciated that since the convex surfaces of the lenses 231 in the lens layer 23 face the first base substrate 21 and the second refractive index layer 24 fits the convex surfaces of the lenses 231, a plurality of recesses are formed on a surface of the second refractive index layer 24 away from the first base substrate 21 and match in a one-to-one correspondence with the convex surfaces of the lenses 231. During manufacturing of the lens layer 23, the organic layer with recesses may be firstly formed by a vapor deposition process or the like, and then the lens layer 23 may be formed by a sputtering process or the like.

In FIG. 2, after a light beam is emitted to and modulated by a lens 231, an emitting angle of the light beam is greatly converged, and the converged degree of the light beam is inversely related to a curvature radius of the convex surface of the lens 231, and is positively related to a difference between the refractive index of the lens 231 and the refractive index of the second refractive index layer 24 (i.e., the organic layer). In this manner, light beams entering the corresponding filter portion 251 can be greatly increased, thereby improving the optical coupling efficiency, and thus reducing the cross color.

Optionally, the refractive index of the lens layer 23 is in a range from 1.8 to 1.9, for example, the refractive index of the lens layer 23 is 1.85; and the refractive index of the second refractive index layer 24 is in a range from 1.4 to 1.55, for example, the refractive index of the second refractive index layer 24 is 1.47.

Optionally, the second refractive index layer 24 (i.e., the organic layer) is made of a resin material, the first inorganic layer includes silicon nitride, and the second inorganic layer 26 includes silicon oxynitride.

Optionally, the display panel further includes a filling layer 27 disposed between the encapsulation structure layer EPL and the filter layer 25, and a refractive index of the filling layer 27 is smaller than a refractive index of the lens layer 23, so as to prevent the filling layer 27 from affecting a convergence effect of the emitted light beams from the lenses 231.

Optionally, the refractive index of the filling layer 27 is in a range from 1.4 to 1.55. For example, the refractive index of the filling layer 27 is 1.49. The filling layer 27 may be made of an organic material such as epoxy.

In an embodiment of the present disclosure, in the case where the difference between the refractive index of the lens 231 and the refractive index of the second refractive index layer 24 is determined, the smaller a distance between a light-emitting device 22 and the corresponding lens 231 and the larger a diameter of the corresponding lens 231, the better the convergence effect of the lens 231 on light beams.

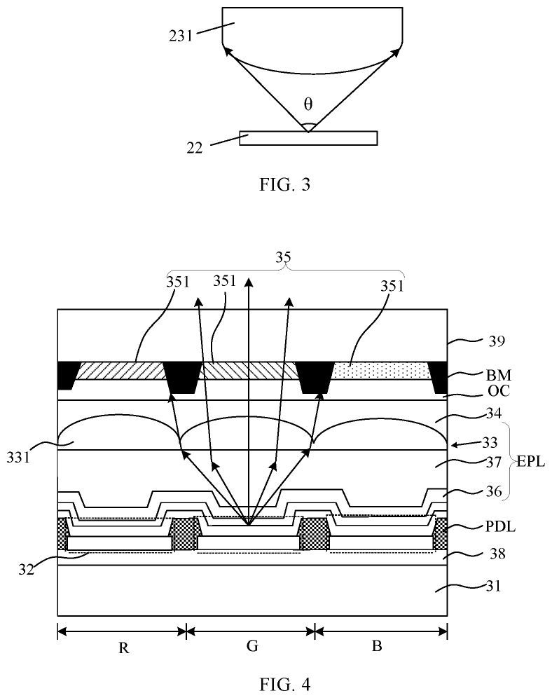

FIG. 3 is a schematic diagram showing an angle at which a light beam from a center of a light-emitting device is emitted to a lens according to an embodiment of the present disclosure. As shown in FIG. 3, in some embodiments, an angle θ of a light beam emitted to a lens 231 from a center or center point of a light-emitting device 22 is greater than 65°.

The angle θ of the light beam emitted to the lens 231 from the center or center point of the light-emitting device 22 refers to an angle between connection lines from the center or center point of the light-emitting device 22 to two opposite points respectively on two opposite edges of the lens 231. The angle θ=2*arctan(w/2/H), where w represents an aperture of the lens 231, and H represents a distance between a connection line connecting the two opposite edges (i.e., two opposite points in a diameter direction of a circular lens) of the lens 231 and a light-emitting surface of the light-emitting device 22, where the light-emitting surface of the light-emitting device 22 is parallel to a plane where the lens 231 is located.

In some embodiments, the display panel further includes a pixel defining layer PDL on the first base substrate 21. The pixel defining layer PDL is made of an organic insulating material including, for example, a resin-based material such as polyimide, epoxy, acryl, polyester, photoresist, polyacrylate, polyamide, siloxane, or the like. The pixel defining layer PDL has pixel openings in one-to-one correspondence with the light-emitting devices 22. Each light-emitting device 22 includes a light-emitting layer 223 in a corresponding pixel opening, as well as an anode 221 and a cathode 222. The anode 221 is disposed in the pixel opening defined by the pixel defining layer PDL, and exposed at least partially from the pixel opening. A plurality of anodes 221 are spaced apart by the pixel defining layer PDL. Light-emitting layers 223 of the plurality of light-emitting devices 22 form an integral structure or are formed as one-piece structure, and cathodes 222 of the plurality of light-emitting devices 22 also form an integral structure or are formed as one-piece structure. Sizes of the pixel openings determine a light-emitting area of the light-emitting devices 22. An orthographic projection of the lens 231 on the first base substrate 21 covers and exceeds an entire orthographic projection of a corresponding pixel opening on the first base substrate 21, thereby improving the convergence effect of the lenses 231 on the light beams emitted from the light-emitting devices 22. An orthographic projection of each of the plurality of lenses 231 on the first base substrate 21 covers and exceeds an entire orthographic projection of the anode of a light-emitting device 22 corresponding to the lens on the first base substrate 21. The plurality of pixel openings, the plurality of light-emitting devices 22, the plurality of lenses 231, and the plurality of filter portions 251 are in one-to-one correspondence with each other, respectively.

In addition, the display panel further includes a pixel driving circuit layer 28 on the first base substrate 21. The pixel driving circuit layer 28 includes pixel driving circuits corresponding to the light-emitting devices 22 and configured to provide driving signals for the light-emitting devices 22 to drive the light-emitting devices 22 to emit light.

In some embodiments, the display panel further includes a second base substrate 29. The filter layer 25 is disposed on a side of the second base substrate 29 facing the first base substrate 21, and a black matrix BM is disposed between adjacent filter portions 251. The light beams irradiating onto the black matrix BM from the light-emitting devices 22 are absorbed by the black matrix BM. The second base substrate 29 may be made of the same material as the first base substrate 21, and the black matrix BM may be made of a photosensitive resin.

An overlay layer OC is disposed on a side of the filter layer 25 proximal to the first base substrate 21 and between the filter layer 25 and the filling layer 27. The overlay layer OC may be made of an organic material such as epoxy. In the manufacturing process of the display panel, the light-emitting device layer, the encapsulation structure layer EPL, and the filling layer 27 may be formed on the first base substrate 21; the filter layer 25, the black matrix BM, and the overlay layer OC covering the filter layer 25 and the black matrix BM are formed on the second base substrate 29, and thereafter, the first base substrate 21 and the second base substrate 29 are aligned to form a cell, thereby forming the display panel.

In some embodiments, the plurality of filter portions 251 of the filter layer 25 are divided into a plurality of repeating cells or a plurality of pixels each including a plurality of filter portions 251. In each of the repeating cells, one of the filter portions 251 includes only a scattering particle layer, and the remaining filter portions 251 each include a quantum dot layer mixed with scattering particles. An embodiment in which each repeating cell or pixel includes three filter portions 251 will be illustrated as an example. For example, the display panel includes a red sub-pixel region R, a green sub-pixel region G, and a blue sub-pixel region B. The filter portions 251 in each repeating cell include: a red quantum dot layer in the red sub-pixel region R, a green quantum dot layer in the green sub-pixel region G, and a scattering layer in the blue sub-pixel region B. The red quantum dot layer includes a red quantum dot material and scattering particles, the red quantum dot material emits red light under excitation of blue light, and the scattering particles scatter the light beams. The green quantum dot layer includes a green quantum dot material and scattering particles, the green quantum dot material emits green light under excitation of blue light, and the scattering particles scatter the light beams. The scattering layer in the blue sub-pixel region B is a transparent layer including scattering particles without any quantum dot layer, and thus directly scatters the blue light. Since each of the filter portions 251 contains scattering particles, the light beams emitted from the lenses 231 can be scattered, and therefore, a wide viewing angle of the display panel cannot be affected by the light convergence effect of the lenses 231.

FIG. 4 is a schematic diagram shwong another display panel according to an embodiment of the present disclosure. Similar to the display panel shown in FIG. 2, the display panel shown in FIG. 4 also includes: a first base substrate 31, a light-emitting device layer, a lens layer 33, a second refractive index layer (i.e., a filling layer) 34, and a filter layer 35. The lens layer 33 includes a plurality of lenses 331 disposed in one-to-one correspondence with light-emitting devices 32 and configured to converge light beams emitted from the light-emitting devices 32. Each lens 331 is a convex lens 331 having at least one convex surface. The second refractive index layer 34 matches or fits the convex surface of each lens 331, and a refractive index of the second refractive index layer 34 is smaller than a refractive index of the lens layer 33. The filter layer 35 is disposed on a side of the lens layer 331 away from the light-emitting device layer, and includes a plurality of filter portions 351 disposed in one-to-one correspondence with the plurality of light-emitting devices 32. The structures of the light-emitting device layer and the filter layer 35 are the same as those in FIG. 2, and thus will not be repeated here. In the display panel shown in FIG. 4, the lens layer 33 also includes lenses 331 disposed in one-to-one correspondence with the light-emitting devices 32, and a center of each light-emitting device 32 is located on an optical axis of a corresponding lens 331. The center of the light-emitting device 32 is aligned with an optical axis of the corresponding lens 331.

In the display panel shown in FIG. 4, the lenses 331 can also converge the light beams from the light-emitting device 32, so that light beams entering a corresponding filter portion 351 are increased, and the light beams irradiated on other light-emitting devices 32 are reduced, thereby improving the optical coupling efficiency and the overall display brightness of the display panel, and reducing the cross color.

In the display panel shown in FIG. 4, a refractive index of the lens layer 33 may be the same as that of the lens layer 33 in FIG. 2, and thus will not be repeated here. A refractive index of the second refractive index layer 34 (i.e., the filling layer) in FIG. 4 is in a range from 1.4 to 1.55.

Unlike FIG. 2, a convex surface of each lens is away from the first base substrate 31, and a planar surface of each lens faces the first base substrate 31. The second refractive index layer 34 is disposed on a side of the lenses away from the first base substrate 31, and may be made of the same material (i.e., organic epoxy) as the filling layer in FIG. 2, and a refractive index of the second refractive index layer 34 is 1.49.

The lens layer 33 is a first inorganic layer. The display panel further includes: an inorganic encapsulation layer 36 and an organic encapsulation layer 37. The lens layer 33, the organic encapsulation layer 37 and the inorganic encapsulation layer 36 are sequentially stacked between the filter layer 35 and the plurality of light-emitting devices in a direction from the filter layer 35 to the first base substrate 31. The lens layer 33, the organic encapsulation layer 37 and the inorganic encapsulation layer 36 form an encapsulation structure layer EPL for encapsulating the plurality of light-emitting devices 32, and a refractive index of the organic encapsulation layer 37 is smaller than a refractive index of the lens layer 33.

Optionally, the lens layer 33 is made of silicon nitride, and the organic encapsulation layer 37 and the second refractive index layer 34 (i.e., the filling layer) are each made of a resin.

In FIG. 4, the display panel further includes a pixel driving circuit layer 38, a second base substrate 39, a pixel defining layer PDL, and an overlay layer OC, which have the specific structures as those shown in FIG. 2 and thus will not be repeated here.

As in FIG. 2, in the display panel shown in FIG. 4, an orthographic projection of the lens on the first base substrate 31 covers and exceeds an entire orthographic projection of a corresponding pixel opening on the first base substrate 31, and an angle of a light beam emitted to a lens 331 from a center point of a light-emitting device 32 is greater than 65°. An orthographic projection of each of the plurality of lenses 331 on the first base substrate 31 covers and exceeds an entire orthographic projection of a light-emitting device 32 corresponding to the lens 331 on the first base substrate 31. The plurality of pixel openings, the plurality of light-emitting devices 32, the plurality of lenses 331, and the plurality of filter portions 351 are in one-to-one correspondence with each other, respectively.

In an embodiment, both surfaces of each convex lens are convex surfaces. In such case, the arrangement of other layers is the same as that in FIG. 2, and thus will not be repeated here.

An embodiment of the present disclosure further provides a display device including the display panel as described above. The display device may bean OLED panel, a mobile phone, a tablet, a television, a displayer, a laptop, a digital album, a navigator or any other product or component having a display function. With the display device including the display panel as describe above, the optical coupling efficiency can be increased, and the cross color effect between different sub-pixels can be improved.

It will be appreciated that the above implementations are merely exemplary implementations for the purpose of illustrating the principle of the present disclosure, and the present disclosure is not limited thereto. It will be apparent to one of ordinary skill in the art that various modifications and variations may be made without departing from the spirit or essence of the present disclosure. Such modifications and variations should also be considered as falling into the protection scope of the present disclosure.

1. A display panel, comprising:
a first base substrate;
a plurality of light-emitting devices on the first base substrate;
a lens layer comprising a plurality of lenses on a side of the plurality of light-emitting devices away from the first base substrate and configured to converge light beams emitted from the plurality of light-emitting devices, the plurality of lenses being one-to-one correspondence with the plurality of light-emitting devices; and
a filter layer on a side of the lens layer away from the first base substrate and configured to enable light from the plurality of light-emitting devices to form monochromatic light after the light from the plurality of light-emitting devices passes through the filter layer.

2. The display panel according to claim 1, wherein
each of the plurality of lenses has at least one convex surface.

3. The display panel according to claim 2, wherein
surfaces of the plurality of lenses proximal to the first base substrate are convex surfaces, and
surfaces of the plurality of lenses away from the first base substrate are planar surfaces.

4. The display panel according to claim 2, wherein
surfaces of the plurality of lenses proximal to the first base substrate are planar surfaces, and
surfaces of the plurality of lenses away from the first base substrate are convex surfaces.

5. The display panel according to claim 1, further comprising an organic encapsulation layer between the lens layer and the plurality of light-emitting devices, wherein
a refractive index of the organic encapsulation layer is smaller than a refractive index of the lens layer.

6. The display panel according to claim 5, further comprising an inorganic encapsulation layer, wherein
the lens layer is an inorganic layer, and
the lens layer, the organic encapsulation layer and the inorganic encapsulation layer are sequentially arranged between the filter layer and the plurality of light-emitting devices along a direction from the filter layer to the first base substrate, and
the lens layer, the organic encapsulation layer and the inorganic encapsulation layer form an encapsulation structure layer for encapsulating the plurality of light-emitting devices.

7. The display panel according to claim 6, wherein
the lens layer comprises silicon nitride,
the organic encapsulation layer comprises a resin, and
the inorganic encapsulation layer comprises silicon nitride.

8. The display panel according to claim 5, wherein
the refractive index of the lens layer is in a range from 1.8 to 1.9, and
the refractive index of the organic encapsulation layer is in a range from 1.4 to 1.55.

9. The display panel according to claim 1, wherein
an angle between two light beams emitted from a center of each of the plurality of light-emitting devices respectively toward two opposite edges of a lens directly facing the light-emitting device is greater than 65°.

10. The display panel according to claim 1, further comprising a filling layer on a side of the lens layer proximal to the filter layer, wherein
a refractive index of the filling layer is smaller than a refractive index of the lens layer, and
the filling layer comprises a resin.

11. The display panel according to claim 10, wherein
the refractive index of the filling layer is in a range from 1.4 to 1.55.

12. The display panel according to claim 1, wherein
the plurality of light-emitting devices are configured to emit blue light, and
the filter layer is configured transmit the blue light emitted from the plurality of light-emitting devices, or to generate monochromatic light with a color different from blue light under excitation of the blue light emitted from the plurality of light-emitting devices.

13. The display panel according to claim 12, wherein the filter layer comprises a plurality of filter portions, comprising a red filter portion, a green filter portion, and a blue filter portion,
the red filter portion comprises a red quantum dot material and scattering particles, the red quantum dot material emits red light under excitation of blue light, and the scattering particles of the red filter portion scatter light beams,
the green filter portion comprises a green quantum dot material and scattering particles, the green quantum dot material emits green light under excitation of blue light, and the scattering particles of the green filter portion scatter light beams, and
the blue filter portion is a transparent layer comprising scattering particles without any quantum dot layer.

14. The display panel according to claim 1, further comprising a pixel defining layer on the first base substrate, wherein the pixel defining layer is configured to define a plurality of pixel openings in which the plurality of light-emitting devices are formed respectively.

15. The display panel according to claim 14, wherein
an orthographic projection of each of the plurality of lenses on the first base substrate covers and exceeds an entire orthographic projection of a pixel opening corresponding to the lens on the first base substrate.

16. The display panel according to claim 14, wherein
each of the plurality of light-emitting devices comprises a cathode, a light-emitting layer, and an anode in a corresponding pixel opening and sequentially arranged along a direction from the filter layer to the first base substrate.

17. The display panel according to claim 16, wherein
the anodes of the plurality of light-emitting devices are spaced apart by the pixel defining layer,
the light-emitting layers of the plurality of light-emitting devices are formed as one-piece structure, and
the cathodes of the plurality of light-emitting devices are formed as one-piece structure.

18. The display panel according to claim 1, further comprising:
a second base substrate on a side of the filter layer away from the first base substrate; and
an overlay layer on a side of the filter layer proximal to the first base substrate and comprising a resin.

19. A display device, comprising:
the display panel according to claim 1; and
a driving circuit layer between the first base substrate and the plurality of light-emitting devices and configured to provide driving signals for the plurality of light-emitting devices to drive the plurality of light-emitting devices to emit light.

20. A method for manufacturing a display panel, comprising:
providing a first base substrate;
forming a plurality of light-emitting devices on the first base substrate;
forming a lens layer comprising a plurality of lenses on a side of the plurality of light-emitting devices away from the first base substrate, so that the plurality of lenses are in one-to-one correspondence with the plurality of light-emitting devices, wherein the lens layer is configured to converge light beams emitted from the plurality of light-emitting devices; and
forming a filter layer on a side of the lens layer away from the first base substrate, wherein the filter layer is configured to enable light from the plurality of light-emitting devices to form monochromatic light after the light from the plurality of light-emitting devices passes through the filter layer.
